(19) United States
(12) Patent Application Publication
(10) Pub. No.: US 2018/0233383 A1
(43) Pub. Date: Aug. 16, 2018

(54) SUBSTRATE TREATMENT APPARATUS AND MANUFACTURING METHOD OF SEMICONDUCTOR DEVICE

(71) Applicant: TOSHIBA MEMORY CORPORATION, Minato-ku (JP)

(72) Inventors: Hiroaki ASHIDATE, Mie (JP); Hiroyasu Iimori, Mie (JP); Katsuhiro Sato, Yokkaichi (JP)

(73) Assignee: TOSHIBA MEMORY CORPORATION, Minato-ku (JP)

(21) Appl. No.: 15/703,630

(22) Filed: Sep. 13, 2017

(30) Foreign Application Priority Data
Feb. 15, 2017 (JP) 2017-026262
Aug. 8, 2017 (JP) 2017-153341

(51) Int. Cl. H01L 21/67; H01L 21/311

(52) U.S. Cl. CPC H01L 21/6708; H01L 21/02164; H01L 21/31111

(57) ABSTRACT

According to an embodiment, a substrate treatment apparatus includes a tank and a control mechanism. The tank houses a substrate including a silicon oxide film and a silicon nitride film, and receives a supply of a phosphoric acid solution capable of selectively etching the silicon nitride film rather than the silicon oxide film. The control mechanism controls an etching state of the silicon nitride film in the tank, by alternately switching two modes based on preset time allocation. The two modes include a first mode in which a first phosphoric acid solution is contact with the substrate and a second mode in which a second phosphoric acid solution with a selection ratio of the silicon nitride film to the silicon oxide film different from that of the first phosphoric acid solution, is contact with the substrate.

### CROSS-REFERENCE TO RELATED APPLICATIONS

This application is based upon and claims the benefit of priority from Japanese Patent Applications No. 2017-026262, filed on Feb. 15, 2017 and No. 2017-153341, filed on Aug. 8, 2017; the entire contents of which are incorporated herein by reference.

### FIELD

An embodiment of the present invention relates to a substrate treatment apparatus and a manufacturing method of a semiconductor device.

### BACKGROUND

Steps of treating substrates including silicon nitride films and silicon oxide films, include a selective etching on the silicon nitride films rather than the silicon oxide films.

During such etching, for example, when the selection ratio of the silicon nitride films is too high, etching of the silicon nitride films may be inhibited. On the other hand, when the selection ratio is too low, not only the silicon nitride films but also the silicon oxide films not to be treated may be etched.

An embodiment according to the present invention provides a substrate treatment apparatus and a semiconductor device manufacturing method, in which selective etching treatment on a silicon nitride film rather than a silicon oxide film can be optimized.

### BRIEF DESCRIPTION OF THE DRAWINGS

FIG. 1 is a schematic diagram schematically illustrating a configuration of a substrate treatment apparatus according to a first embodiment;

FIG. 2 is a cross-sectional view of a substrate to be treated;

FIG. 3 is a graph showing the details of control performed by a control mechanism;

FIG. 4 is a schematic diagram schematically illustrating a configuration of a substrate treatment apparatus according to a first modification;

FIG. 5 is a schematic diagram schematically illustrating a configuration of a substrate treatment apparatus according to a second embodiment;

FIG. 6 is a schematic diagram schematically illustrating a configuration of a substrate treatment apparatus according to a second modification;

FIG. 7 is a schematic diagram schematically illustrating a configuration of a substrate treatment apparatus according to a third embodiment;

FIG. 8 is a schematic diagram schematically illustrating a configuration of a substrate treatment apparatus according to a third modification; and

FIG. 9 is a schematic diagram schematically illustrating a configuration of a substrate treatment apparatus according to a fourth embodiment.

### DETAILED DESCRIPTION

Embodiments will now be explained with reference to the accompanying drawings. The present invention is not limited to the embodiments.

### First Embodiment

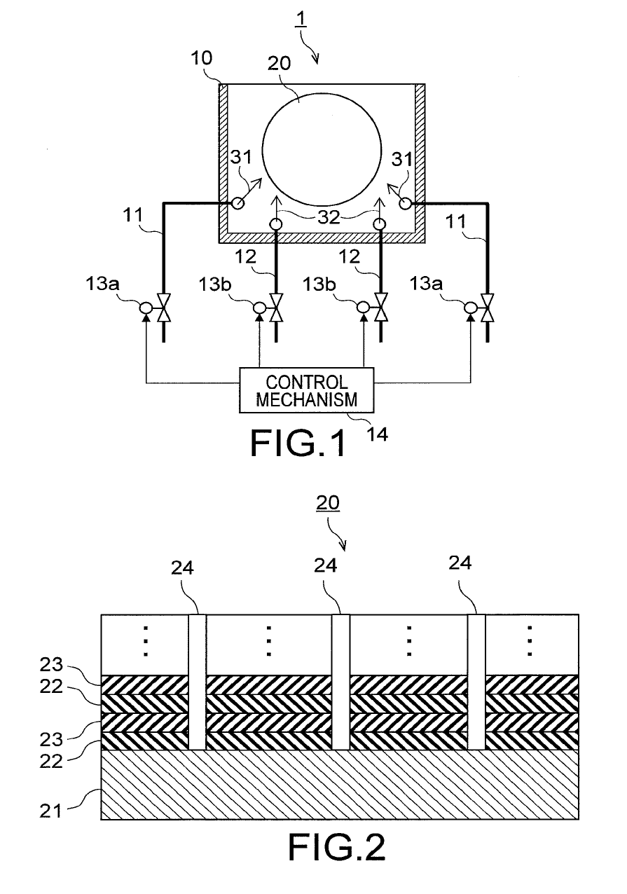

FIG. 1 is a schematic diagram schematically illustrating a configuration of a substrate treatment apparatus according to a first embodiment. A substrate treatment apparatus 1 according to the present embodiment includes a tank 10, first piping 11, second piping 12, valves 13a and 13b, and a control mechanism 14. The substrate treatment apparatus 1 performs etching treatment on a plurality of substrates 20 collectively in the tank 10, and is a so-called batch type etching apparatus.

FIG. 2 is a cross-sectional view of one of the substrates 20 to be treated. The substrate 20 includes a silicon substrate 21, silicon oxide films (SiO₂) 22, and silicon nitride films (SiN) 23. The silicon oxide films 22 and the silicon nitride films 23 are alternately stacked on the silicon substrate 21. Each slit 24 penetrates a part of these films. The silicon nitride films 23 are etched through the slits 24.

Referring back to FIG. 1, the first piping 11 and the second piping 12 are each connected to the tank 10. Through the first piping 11, a first phosphoric acid solution 31 is supplied into the tank 10. Through the second piping 12, a second phosphoric acid solution 32 is supplied into the tank 10.

The first phosphoric acid solution 31 and the second phosphoric acid solution 32 have different selection ratios of the silicon nitride films 23 to the silicon oxide films 22. To obtain such different selection ratios, for example, these solutions in the tank 10 may be different from each other in at least one of the phosphoric acid concentration, the concentration (the silica concentration) of a silicon compound, the viscosity, and the phosphoric acid solution temperature. In this case, the phosphoric acid solution with the higher phosphoric acid concentration has the higher selection ratio, and the phosphoric acid solution with the higher silica concentration or the higher viscosity has the higher selection ratio.

In addition, a case is possible where one of the phosphoric acid solutions includes an additive such as a hydrogen fluoride (HF) which increases the selection ratio, whereas the other does not include such an additive. Moreover, a case is possible where one of the phosphoric acid solutions is in a boiling state, whereas the other is in a non-boiling state. In this case, the phosphoric acid solution in the boiling state has the lower selection ratio.

The valves 13a are provided to the first piping 11. The valves 13b are provided to the second piping 12. When the valves 13a are in open states, the first phosphoric acid solution 31 is supplied into the tank 10. When the valves 13b are in open states, the second phosphoric acid solution 32 is supplied into the tank 10.

The control mechanism 14 controls opening/closing of the valves 13a and the valves 13b such that two modes in which the respective selection ratios of the silicon nitride films 23 to the silicon oxide film 22 are different from each other, are alternately switched based on preset time allocation.

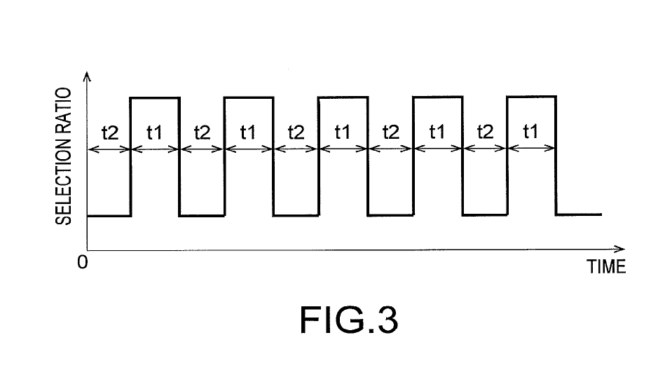

FIG. 3 is a graph showing the details of control performed by the control mechanism 14. For example, when the selection ratio of the first phosphoric acid solution 31 is higher than the selection ratio of the second phosphoric acid solution 32, the control mechanism 14 opens the valves 13a and closes the valves 13b during sections t1 shown in FIG. 3. On the other hand, the control mechanism 14 closes the valves 13a and opens the valves 13b during sections t2.

The time allocation for the sections t1 and t2 is set, as appropriate, based on the shapes or positions of the silicon oxide films 22 and the silicon nitride films 23, for example. Accordingly, the control mechanism 14 desirably has a function of allowing free setting of the time allocation for the sections t1 and t2 according to operation performed by a user. This function enables optimum etching of the silicon nitride films 23 according to various forms of the substrates 20.

Next, a description is given of manufacturing steps of a semiconductor device according to the present embodiment. Here, a simple description is given of a step of performing etching treatment on the silicon nitride films 23, among steps of manufacturing a 3D memory having electrode layers (word lines) stacked therein.

First, the plurality of substrates 20 are housed in the tank 10. Next, the control mechanism 14 controls the valves 13a and the valves 13b based on the time allocation set for the sections t1 and t2 as shown in FIG. 3.

During the sections t1, the valves 13a are open and the first phosphoric acid solution 31 is supplied into the tank 10. The first phosphoric acid solution 31 etches the silicon nitride films 23 through the slits 24. During this etching, the selection ratio of the silicon nitride films 23 is increased. Thus, when a certain time has elapsed, deposition of silica starts in the vicinity of the slits 24 (see FIG. 2) in each of the substrates 20. When an excessive amount of silica is deposited, the vicinity of the slits 24 is covered with silica, and no electrode layer may be formed at the following step. For this reason, before such a situation occurs, the control mechanism 14 closes the valves 13a and opens the valves 13b in the present embodiment.

During the sections t2, the second phosphoric acid solution 32 is supplied into the tank 10. The second phosphoric acid solution 32 also etches the silicon nitride films 23 through the slits 24. During this etching, since the selection ratio of the silicon nitride films 23 is decreased, silica deposited in the vicinity of the slits 24 can be etched. However, when a certain time has elapsed, the silicon oxide films 22 near the slits 24 in each of the substrates 20 may be etched. For this reason, in order to avoid etching of the silicon oxide films 22, the control mechanism 14 again opens the valves 13a and closes the valves 13b in the present embodiment. In this way, the substrate treatment apparatus 1 alternately repeats the two modes in which the respective selection ratios are different from each other, and thereby performs etching of the silicon nitride films 23.

After the etching treatment on the silicon nitride films 23 is ended, for example, tungsten (W)—including electrode layers for a 3D memory are formed between the silicon oxide films 22. That is, the electrode layers are formed by being replaced with the silicon nitride films 23.

According to the present embodiment having been described above, the two different phosphoric acid solutions 31, 32 having the different selection ratios of the silicon nitride films 23 are alternately supplied into the tank 10 under control of the valves 13a and the valves 13b by the control mechanism 14, based on the preset time allocation. As a result of adjustment of the selection ratios in this way, silica deposition can be suppressed to a minimum level, and etching of the silicon oxide films 22 is avoided. As a result, selective etching treatment on the silicon nitride films 23 rather than the silicon oxide films 22 can be optimized.

(First Modification)

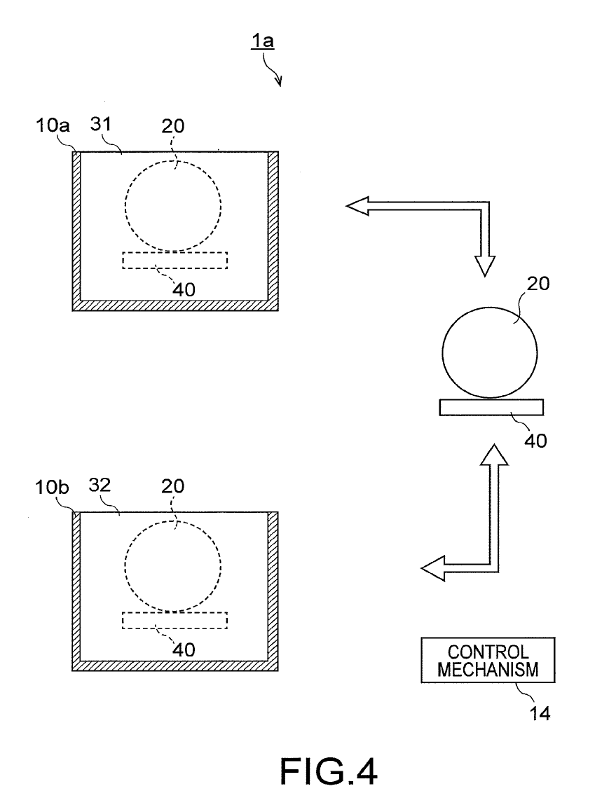

FIG. 4 is a schematic diagram schematically illustrating a configuration of a substrate treatment apparatus according to a first modification. In FIG. 4, components identical to those of the aforementioned substrate treatment apparatus 1 are denoted by the same reference numerals, and a detailed explanation thereof is omitted.

A substrate treatment apparatus 1a according to the present modification includes a first tank 10a, a second tank 10b, the control mechanism 14, and a conveyance mechanism 40. The substrate treatment apparatus 1a is also a batch type etching apparatus, like the substrate treatment apparatus 1.

The first phosphoric acid solution 31 is supplied into the first tank 10a. On the other hand, the second phosphoric acid solution 32 is supplied into the tank 10b.

The conveyance mechanism 40 conveys the substrates 20 between the first tank 10a and the second tank 10b under control by the control mechanism 14. The control mechanism 14 conveys the substrates 20 into the first tank 10a during the sections t1 (see FIG. 3) and conveys the substrates 20 into the second tank 10b during the sections t2 (see FIG. 3).

Respective phosphoric acid solutions having different selection ratios of the silicon nitride films 23 are stored in the first tank 10a and the second tank 10b. Accordingly, as a result of reciprocal movement of the substrates 20 between the first tank 10a and the second tank 10b, the selection ratio of the silicon nitride films 23 is switched between the two modes alternately. Therefore, according to the present modification, selective etching treatment on the silicon nitride films 23 rather than the silicon oxide films 22 can be optimized, as in the first embodiment.

### Second Embodiment

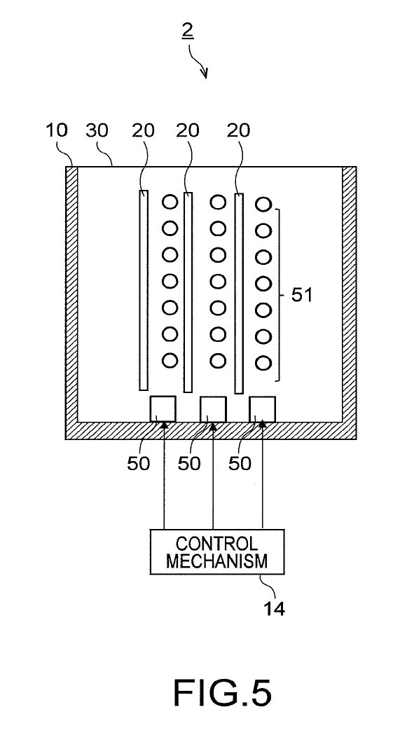

FIG. 5 is a schematic diagram schematically illustrating a configuration of a substrate treatment apparatus according to a second embodiment. In FIG. 5, components identical to those of the aforementioned substrate treatment apparatus 1 are denoted by the same reference numerals, and a detailed explanation thereof is omitted.

A substrate treatment apparatus 2 according to the present embodiment includes the tank 10, the control mechanism 14, and a plurality of air bubble generators 50. The substrate treatment apparatus 2 is also a batch-type etching apparatus, like the substrate treatment apparatus 1.

The plurality of substrates 20 are housed in the tank 10, and a phosphoric acid solution 30 is supplied into the tank 10. The phosphoric acid solution 30 may be the same as the aforementioned first phosphoric acid solution 31, or as the aforementioned second phosphoric acid solution 32.

The air bubble generators 50 are set on the bottom of the tank 10. The air bubble generators 50 intermittently jet out air bubbles 51 under control by the control mechanism 14. The air bubbles 51 pass through at surface sides of the substrates 20 toward the upper part of the tank 10. When the air bubbles 51 are generated in the phosphoric acid solution 30, the flow speed of the phosphoric acid solution 30 becomes higher and the selection ratio of the silicon nitride films 23 becomes lower. When the air bubbles 51 disappear, the flow speed of the phosphoric acid solution 30 becomes lower (restores the initial state) and the selection ratio of the silicon nitride films 23 becomes higher. When the silicon nitride films 23 are etched, a silica-concentration boundary layer is formed on a surface of each of the substrates 20. That is, a phenomenon occurs in which the silica concentration in the slits 24 is different from the silica concentration of the entire phosphoric acid solution 30. When the flow speed of the phosphoric acid solution 30 becomes higher due to the air bubbles 51, the silica-concentration boundary layer on the surface of each of the substrates 20 becomes thinner. That is, the silica concentration in the slits 24 is decreased so that the selection ratio is decreased. As a result of intermittently jetting out the air bubbles 51 based on this phenomenon, the selection ratio can be switched.

Under control by the control mechanism 14, the air bubble generators 50 are switched between a first mode in which the air bubbles 51 are generated and a second mode in which generation of the air bubbles 51 is halted, alternately based on preset time allocation. Specifically, during the sections t1 shown in FIG. 3, the air bubble generators 50 are driven in the second mode, and during the sections t2, the air bubble generators 50 are driven in the first mode. Accordingly, the selection ratio of the silicon nitride films 23 is increased and decreased in the tank 10, according to change of the flow speed of the phosphoric acid solution 30.

According to the present embodiment having been described above, the air bubbles 51 are generated intermittently in the phosphoric acid solution 30 under control of the air bubble generators 50 by the control mechanism 14. Accordingly, the two different flow speeds of the phosphoric acid solution 30 is alternately repeated. Thus, the selection ratios of the silicon nitride films 23 can be alternately switched between the two modes. Therefore, selective etching treatment on the silicon nitride films 23 rather than the silicon oxide films 22 can be optimized.

(Second Modification)

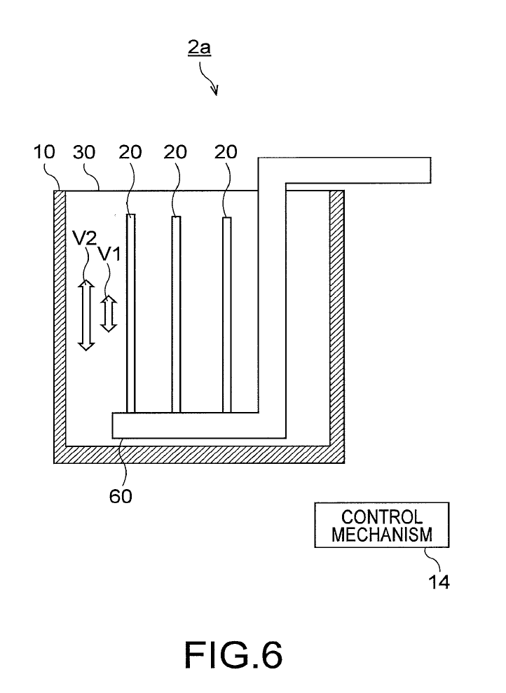

FIG. 6 is a schematic diagram schematically illustrating a configuration of a substrate treatment apparatus according to a second modification. In FIG. 6, components identical to those of the aforementioned substrate treatment apparatus 2 are denoted by the same reference numerals, and a detailed explanation thereof is omitted.

A substrate treatment apparatus 2a according to the present modification includes the tank 10, the control mechanism 14, and an oscillation mechanism 60. The substrate treatment apparatus 2a is also a batch-type etching apparatus, like the substrate treatment apparatus 2.

The oscillation mechanism 60 oscillates the substrates 20 at two different speeds in the tank 10 under control by the control mechanism 14. The oscillation mechanism 60 oscillates the substrates 20 at a low speed V1 (see arrow V1 in FIG. 6) during the sections t1 shown in FIG. 3, and oscillates the substrates 20 at a high speed V2 (see arrow V2 in FIG. 6) during the sections t2. The oscillation mechanism 60 oscillates the substrates 20 by repeatedly moving up and down in the vertical direction in the tank 10. However, a direction for oscillating the substrates 20 is not limited to the vertical direction, and may be the horizontal direction.

When the speed of oscillating the substrates 20 is lower, the flow speed of the phosphoric acid solution 30 in the tank 10 is lower and the selection ratio of the silicon nitride films 23 is higher. In contrast, when the oscillating speed is higher, the flow speed of the phosphoric acid solution 30 is also higher and the selection ratio is lower. The silicon nitride films 23 are etched, so that a silica-concentration boundary layer is formed on a surface of each of the substrates 20. That is, a phenomenon occurs in which the silica concentration in the slits 24 is different from the silica concentration of the entire phosphoric acid solution 30. When the flow speed of the phosphoric acid solution 30 relative to the substrates 20 becomes higher due to the oscillation speed V1, the silica-concentration boundary layer on the surface of each of the substrates 20 becomes thinner. That is, the silica concentration in the slits 24 is decreased and the selection ratio is decreased. As a result of switching between the oscillation speeds V1 and V2 based on this phenomenon, the selection ratios can be switched.

According to the present modification having been described above, as a result of change of the speed for oscillating the substrates 20, the flow speed of the phosphoric acid solution 30 changes. Accordingly, the selection ratios of the silicon nitride films 23 are switched. Therefore, selective etching treatment on the silicon nitride films 23 rather than the silicon oxide films 22 can be optimized.

### Third Embodiment

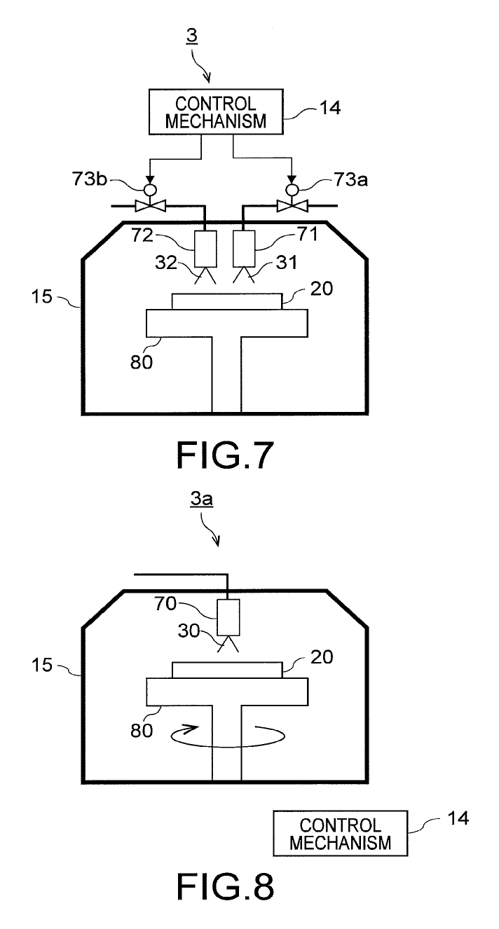

FIG. 7 is a schematic diagram schematically illustrating a configuration of a substrate treatment apparatus according to a third embodiment. In FIG. 7, components identical to those of the aforementioned substrate treatment apparatus 1 are denoted by the same reference numerals, and a detailed explanation thereof is omitted.

A substrate treatment apparatus 3 according to the present embodiment includes the control mechanism 14, a chamber 15, a first nozzle 71, a second nozzle 72, valves 73a and 73b, and a stage 80. The substrate treatment apparatus 3 performs etching treatment on the substrates 20 one by one in the chamber 15, and is a so-called single-substrate etching apparatus.

In the chamber 15, one of the substrates 20 is supported on the stage 80. Further, in the chamber 15, the first nozzle 71 and the second nozzle 72 are provided above the stage 80. The first nozzle 71 jets out the first phosphoric acid solution 31, and the second nozzle 72 jets out the second phosphoric acid solution 32. The first phosphoric acid solution 31 and the second phosphoric acid solution 32 are jetted toward a surface of the substrate 20. The stage 80 may rotate about a rotational axis which is in a substantially vertical direction. Further, while the stage 80 is rotating, the first phosphoric acid solution 31 or the second phosphoric acid solution 32 may be jetted to a surface of the substrate 20.

Each of the valve 73a and the valve 73b is opened and closed under control by the control mechanism 14. When the valve 73a is open, the first phosphoric acid solution 31 is supplied into the chamber 15 through the first nozzle 71. When the valve 73b is open, the second phosphoric acid solution 32 is supplied into the chamber 15.

The control mechanism 14 opens the valve 73a and closes the valve 73b so as to cause the first nozzle 71 to jet out the first phosphoric acid solution 31 into the chamber 15 during the sections t1 (see FIG. 3). In addition, the control mechanism 14 closes the valve 73a and opens the valve 73b so as to cause the second nozzle 72 to jet out the second phosphoric acid solution 32 into the chamber 15 during the sections t2 (see FIG. 3). As a result, the selection ratios of the silicon nitride films 23 are alternately repeated between the two modes.

According to the present embodiment having been described above, the two different phosphoric acid solutions 31, 32 having the different selection ratios of the silicon nitride films 23 are alternately jetted to a substrate of the substrate 20 in the chamber 15 based on preset time allocation, under control of the valve 73a and the valve 73b by the control mechanism 14. Therefore, like the batch type, the single-substrate processing type can also optimize selective etching treatment on the silicon nitride films 23 rather than the silicon oxide films 22.

(Third Modification)

FIG. 8 is a schematic diagram schematically illustrating a configuration of a substrate treatment apparatus according to a third modification. In FIG. 8, components identical to those of the aforementioned substrate treatment apparatus 3 are denoted by the same reference numerals, and a detailed explanation thereof is omitted.

A substrate treatment apparatus 3a according to the present modification includes the control mechanism 14, the chamber 15, a nozzle 70, and the stage 80. The substrate treatment apparatus 3a is also a single-substrate etching apparatus, like the substrate treatment apparatus 3.

In the present embodiment, the stage 80 functions as a rotatory mechanism that rotates at two different rotational speeds under control by the control mechanism 14. Specifically, the stage 80 rotates at a low speed during the sections t1 shown in FIG. 3, and rotates at a high speed during the sections t2. The rotation direction during the sections t1 and that during the sections t2 may be the same or may be opposite to each other.

When the stage 80 rotates, the substrate 20 supported on the stage 80 also rotates. Accordingly, when the nozzle 70 jets out the phosphoric acid solution 30 to a surface of the substrate 20 while the substrate 20 is rotating at a low speed, the flow speed of the phosphoric acid solution 30 on the surface of the substrate 20 becomes low. As a result, the selection ratio of the silicon nitride films 23 becomes higher.

In contrast, when the nozzle 70 jets out the phosphoric acid solution 30 to a surface of the substrate 20 while the substrate 20 is rotating at a high speed, the flow speed of the phosphoric acid solution 30 on the surface of the substrate 20 becomes high. As a result, the selection ratio of the silicon nitride films 23 becomes lower.

According to the present modification having been described above, the control mechanism 14 causes the stage 80 to rotate alternately at the two different rotational speeds, and thus, the two different flow speeds of the phosphoric acid solution 30 are alternately repeated on the surface of the substrate 20. As a result, the selection ratios of the silicon nitride films 23 are alternately switched between the two modes, as in the third embodiment. Therefore, etching treatment on the silicon nitride films 23 can be optimized.

### Fourth Embodiment

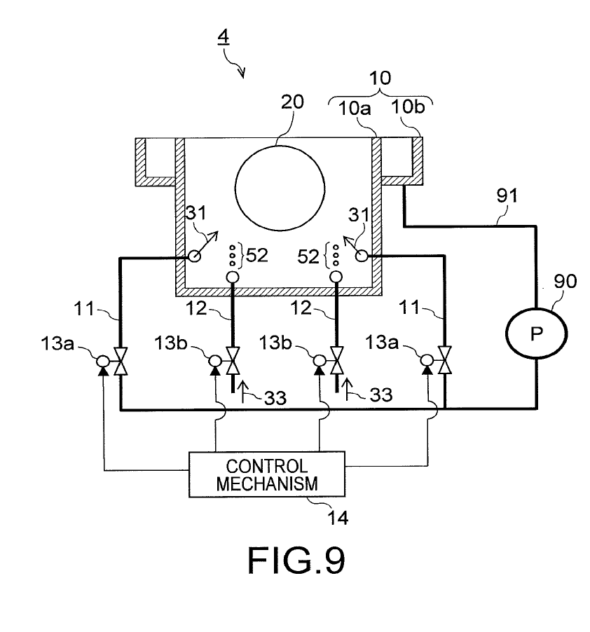

FIG. 9 is a schematic diagram schematically illustrating a configuration of a substrate treatment apparatus according to a fourth embodiment. In FIG. 9, components identical to those of the aforementioned substrate treatment apparatus 1 are denoted by the same reference numerals, and a detailed explanation thereof is omitted.

A substrate treatment apparatus 4 according to the present embodiment includes a pump 90 and third piping 91, in addition to the components of the substrate treatment apparatus 1 according to the first embodiment. Further, in the present embodiment, the tank 10 includes an inner tank 10a and an outer tank 10b.

The substrate 20 is housed in the inner tank 10a. Moreover, the first piping 11 and the second piping 12 are each connected to the inner tank 10a. Through the first piping 11, the aforementioned first phosphoric acid solution 31 is supplied into the inner tank 10a. On the other hand, through the second piping 12, an air bubble generation liquid 33 is supplied into the inner tank 10a.

The air bubble generation liquid 33 is water including any of nitrogen (N₂), hydrogen peroxide (H₂O₂), ozone (O₃), oxygen (O₂), and carbon dioxide (CO₂), or is a phosphoric acid solution. When the air bubble generation liquid 33 is supplied into the inner tank 10a, air bubbles 52 are generated. In the present embodiment, in order to generate the air bubbles 52, the temperature of the first phosphoric acid solution 31 in the inner tank 10a is adjusted to a predetermined temperature (for example, 160° C.), and the content of the aforementioned substance in the air bubble generation liquid 33 is adjusted. In a case where the air bubble generation liquid 33 is a phosphoric acid solution, the phosphate concentration of the phosphoric acid solution may be equal to, or may be unequal to that of the first phosphoric acid solution 31. The substance included in the air bubble generation liquid 33 is not limited to a particular substance, as long as the substance generates, in the first phosphoric acid solution 31 the temperature of which has been adjusted to the predetermined temperature, the air bubbles 52 of nitrogen (N₂), hydrogen peroxide (H₂O₂), ozone (O₃), oxygen (O₂), or carbon dioxide (CO₂).

In a case where the silicon nitride films 23 are selectively etched by the substrate treatment apparatus 4 having the above configuration, the control mechanism 14 controls opening/closing of the valves 13a and the valves 13b based on time allocation for the sections t1 and t2 set as shown in FIG. 3, as in the first embodiment. During the sections t1, the valves 13a are open and the valves 13b are closed. Accordingly, the first phosphoric acid solution 31 is supplied into the tank 10. On the other hand, during the sections t2, the valves 13a are closed and the valves 13b are open. Accordingly, the air bubbles 52 are generated, the flow speed of the first phosphoric acid solution 31 in the inner tank 10a becomes higher, and the selection ratio of the silicon nitride films 23 becomes lower.

When the phosphoric acid solution is stored in the inner tank 10a overflows during the etching, the overflowing phosphoric acid solution is housed in the outer tank 10b. The housed phosphoric acid solution is discharged from the outer tank 10b through the third piping 91 by the pump 90. The discharged phosphoric acid solution is supplied again into the inner tank 10a through the first piping 11. That is, the present embodiment is provided with a circulation path for the phosphoric acid solution. Accordingly, the phosphoric acid solution can be reused without any waste.

According to the present embodiment having been described above, opening and closing operations of the valves 13b are repeated under control by the control mechanism 14, and thus, the air bubbles 52 are intermittently generated in the inner tank 10a. Accordingly, the two different flow speeds of the phosphoric acid solution are alternately repeated. Thus, the selection ratios of the silicon nitride films 23 can be alternately switched between the two modes. Therefore, selective etching treatment on the silicon nitride films 23 rather than the silicon oxide films 22 can be optimized.

In particular, if the air bubble generation liquid 33 is water including any of hydrogen peroxide (H₂O₂), ozone (O₃), and oxygen (O₂), or is a phosphoric acid solution, the first phosphoric acid solution 31 with at least oxidizability is formed in the inner tank 10a. Accordingly, the selection ratio of the silicon nitride films to the silicon oxide films can be further increased. The substance included in the air bubble generation liquid 33 is not limited to a particular substance as long as the substance generates gas for forming an oxidation atmosphere in the first phosphoric acid solution 31 the temperature of which has been adjusted to the predetermined temperature.

The substrate treatment apparatus 4 according to the present embodiment may include the air bubble generator 50 described in the second embodiment. In this case, not only the air bubbles 52 but also the air bubbles 51 generated by the air bubble generator 50 are used, so that more air bubbles can be generated in the inner tank 10a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A substrate treatment apparatus comprising:
a tank to house a substrate including a silicon oxide film and a silicon nitride film, and to receive a supply of a phosphoric acid solution capable of selectively etching the silicon nitride film rather than the silicon oxide film; and
a control mechanism to control an etching state of the silicon nitride film in the tank, by alternately switching two modes based on a preset time allocation, the two modes including a first mode in which a first phosphoric acid solution is contact with the substrate and a second mode in which a second phosphoric acid solution with a selection ratio of the silicon nitride film to the silicon oxide film different from that of the first phosphoric acid solution, is contact with the substrate.

2. The substrate treatment apparatus according to claim 1, further comprising:
first piping through which the first phosphoric acid solution is supplied to the tank;
second piping through which the second phosphoric acid solution is supplied to the tank; and
a plurality of valves provided respectively to the first piping and the second piping, wherein
the control mechanism controls the plurality of valves based on the time allocation.

3. The substrate treatment apparatus according to claim 2, wherein
at least one of a phosphate concentration, concentration of a silicon compound, viscosity, a boiling state, and a temperature is deferent between the first phosphoric acid solution and the second phosphoric acid solution.

4. The substrate treatment apparatus according to claim 1, wherein
the control mechanism changes a flow speed of the phosphoric acid solution in the tank so as to correspond to the two modes.

5. The substrate treatment apparatus according to claim 4, further comprising an air bubble generator to intermittently generate air bubbles in the phosphoric acid solution under control by the control mechanism.

6. The substrate treatment apparatus according to claim 4, further comprising an oscillation mechanism to oscillate the substrate in the tank alternatively at two different speeds respectively corresponding to the two modes, under control by the control mechanism.

7. The substrate treatment apparatus according to claim 4, further comprising:
first piping through which the first phosphoric acid solution is supplied to the tank;
second piping through which an air bubble generation liquid which generates air bubbles in the tank storing the first phosphoric acid solution, is supplied to the first phosphoric acid solution so as to form the second phosphoric acid solution state; and
a plurality of valves provided respectively to the first piping and the second piping, wherein
the control mechanism controls the plurality of valves based on the time allocation.

8. The substrate treatment apparatus according to claim 7, wherein the air bubble generation liquid is water including any of hydrogen peroxide, ozone, oxygen, and carbon dioxide, or is a phosphoric acid solution.

9. A manufacturing method of a semiconductor device, the method comprising:
supplying a phosphoric acid solution into a tank;
housing a substrate including a silicon oxide film and a silicon nitride film in the tank; and
selectively etching, in the tank, the silicon nitride film rather than the silicon oxide film, by alternately switching two modes based on a preset time allocation, the two modes including a first mode in which a first phosphoric acid solution is contact with the substrate and a second mode in which a second phosphoric acid solution with a selection ratio of the silicon nitride film to the silicon oxide film different from that of the first phosphoric acid solution, is contact with the substrate.
